(19) United States
(12) Patent Application Publication
(10) Pub. No.: US 2026/0090439 A1
(43) Pub. Date: Mar. 26, 2026

(54) CHIP MOUNTING FIXTURE AND CHIP MOUNTING PROCESS

(71) Applicant: SHENZHEN GREPOW BATTERY CO., LTD., Guangdong (CN)

(72) Inventors: Shiyu LIU, Guangdong (CN); Bing GUO, Guangdong (CN); Gang LI, Guangdong (CN); Long LI, Guangdong (CN); Miao YANG, Guangdong (CN)

(21) Appl. No.: 19/111,328

(22) PCT Filed: Jan. 17, 2023
(86) PCT No.: PCT/CN2023/072646

§ 371 Date: Mar. 13, 2025

(30) Foreign Application Priority Data
Sep. 23, 2022 (CN) 202211166676.9

(51) Int. Cl. H10W 72/00; H10P 72/10

(52) U.S. Cl. CPC H10W 72/07178; H10P 72/16; H10W 72/07236

(57) ABSTRACT

The present invention relates to the technical field of chip fixtures. Disclosed is a chip mounting fixture, comprising: a fixture body, wherein the fixture body is provided with chip slots which are uniformly distributed in an array and are used for accommodating chips, recessed wire slots are formed at the chip slots, and the wire slots extend to the outer sides of the chip slots. The present invention facilitates taking out a processed chip product, and the operation mode is convenient.

### TECHNICAL FIELD

The present disclosure relates to the technical field of chip fixtures, and in particular to a chip mounting fixture.

### BACKGROUND OF THE INVENTION

During chip processing, it is usually necessary to install pins on a chip. Therefore, it is necessary to design a fixture to install the chip and the pins, and an upper cover plate and a lower cover plate of the fixture are used to fix the chip during processing. However, the above fixture has the technical defect of being difficult to extract the processed chip, thereby needing improvement.

### BRIEF SUMMARY OF THE INVENTION

In view of the above defects in the prior art, the present disclosure provides a chip mounting fixture to solve the technical problems mentioned in the above Background.

In order to solve the above technical problems, the present disclosure adopts the following technical solution:
a chip mounting fixture, including: a fixture body, where the fixture body is provided with chip slots that are uniformly distributed in an array and configured for accommodating chips, inwardly recessed wire slots are formed at the chip slots, and the wire slots extend to outer sides of the chip slots.

Further, the wire slots between the chip slots in a same linear direction can be communicated with each other.

Further, the chip mounting fixture includes a limiting plate, the limiting plate is mounted on the fixture body, and the limiting plate is provided with one or more solder paste slots fitted with the chip slots.

Further, two solder paste slots are arranged at a corresponding position of the chip slot, the two solder paste slots are arranged in a staggered manner, and a compression band that spans over the chip slot is formed by the two solder paste slots.

Further, the limiting plate is fixed to the fixture body by means of magnetic attraction.

Further, the chip mounting fixture includes a limiting fixture, where the limiting fixture is provided with one or more pin slots fitted with the chip slot and configured for placing straight pins or square pins.

A chip mounting process, including: the chip is placed in the chip slot of the fixture body; the limiting plate is provided with a magnetic element, the limiting plate is mounted on the fixture body by means of magnetic attraction, solder paste is coated onto a bonding pad surface of the chip through the solder paste slot of the limiting plate to form a solder paste band, and the compression band formed between the solder paste slots compresses the chip; and the limiting fixture is placed on the limiting plate, the straight pin/the square pin is placed in the pin slot and attached to the solder paste band for chip mounting, and the chip is extracted from the fixture after completing the above operation.

Further, the straight pin/the square pin is attached to the solder paste band of the chip through surface mount technology (SMT).

Further, the straight pin/the square pin is placed in the pin slot and attached to the solder paste band for chip mounting, including that an opening of the pin slot is designed to have an involute slot structure.

Further, pin columns are arranged at four corners of the limiting fixture, corresponding pin column holes are formed at four corners of the limiting plate, positioning columns are arranged at four corners of the fixture body, and the pin columns of the limiting fixture are matched and fixed with the positioning columns of the fixture body through the pin column holes of the limiting plate; and one or move recessed hand grooves are formed on the fixture body.

Compared with the prior art, the present disclosure has the beneficial effects as follows: the wire slots are designed on the chip slots of the fixture body, such that after the processing, the chip, under the action of an external object, can be extracted from the chip slot through the wire slot, thereby having the advantage of convenient extraction.

### BRIEF DESCRIPTION OF THE DRAWINGS

FIG. 1 is a structural schematic diagram of a chip mounting fixture in an example.

FIG. 2 is a structural schematic diagram of a fixture body in an example.

FIG. 3 is a schematic diagram of a partially enlarged structure of FIG. 2.

FIG. 4 is a structural schematic diagram of a limiting plate in an example.

FIG. 5 is a schematic diagram of a partially enlarged structure of FIG. 4.

FIG. 6 is a structural schematic diagram of a limiting fixture in an example.

FIG. 7 is a schematic diagram of a partially enlarged structure of FIG. 6.

FIG. 8 is a schematic diagram of an exploded structure of a chip mounting fixture in an example.

FIG. 9 is a structural schematic diagram of a chip product.

Reference numerals in the figures: 1. fixture body; 2. chip slot; 3. wire slot; 4. limiting plate; 5. solder paste slot; 6. compression band; 7. limiting fixture; 8. pin slot; 9. chip; 10. square pin; and 11. straight pin.

### DETAILED DESCRIPTION OF THE INVENTION

The present disclosure will be further described in detail below with reference to the accompanying drawings.

The examples described with reference to the accompanying drawings are exemplary and only intended to explain the present disclosure, instead of being construed as limiting the present disclosure. In the description of the present disclosure, it should be understood that the terms “center”, “longitudinal”, “lateral”, “length”, “width”, “thickness”, “upper”, “lower”, “front”, “rear” , “left”, “right”, “vertical”, “horizontal”, “top”, “bottom”, “inner”, “outer”, “clockwise”, “counterclockwise”, etc. indicate azimuthal or positional relations based on those shown in the accompanying drawings only for ease of description of the present disclosure and for simplicity of description, and are not intended to indicate or imply that the referenced device or element must have a particular orientation and be constructed and operative in a particular orientation, and thus may not be interpreted as a limitation on the present disclosure. Furthermore, the terms “first” and “second” are merely for the purpose of description, and cannot be construed as indicating or implying relative importance or implicitly specifying the number of technical features indicated. Thus, a feature defined with “first” and “second” may explicitly or implicitly include one or more of the features. In the description of the present disclosure, “several” and “a plurality of” mean two or more, unless expressly specified otherwise. In the present disclosure, unless otherwise explicitly specified and defined, the terms “mounting”, “connecting”, “connection”, “fixing”, etc. should be understood in a broad sense, for example, they may be a fixed connection, a detachable connection, or an integrated connection; may be a mechanical connection, or an electrical connection; may be a direct connection, or an indirect connection via an intermediate medium; and may be communication inside two elements. For those of ordinary skill in the art, the specific meanings of the above terms in the present disclosure may be understood according to specific circumstances. In the present disclosure, unless otherwise expressly stated and defined, a first feature being “above” or “below” a second feature may include the first and second features being in direct contact or that the first and second features being not in direct contact but being in contact by means of additional features between the first and second features. In addition, the first feature being “over”, “above” and “on the top of” the second feature includes that the first feature is over and above the second feature, or simply means that the level of the first feature is higher than that of the second feature. The first feature being “under”, “below” and “at the bottom of” the second feature includes that the first feature is over and above the second feature, or simply means that the level of the first feature is lower than that of the second feature.

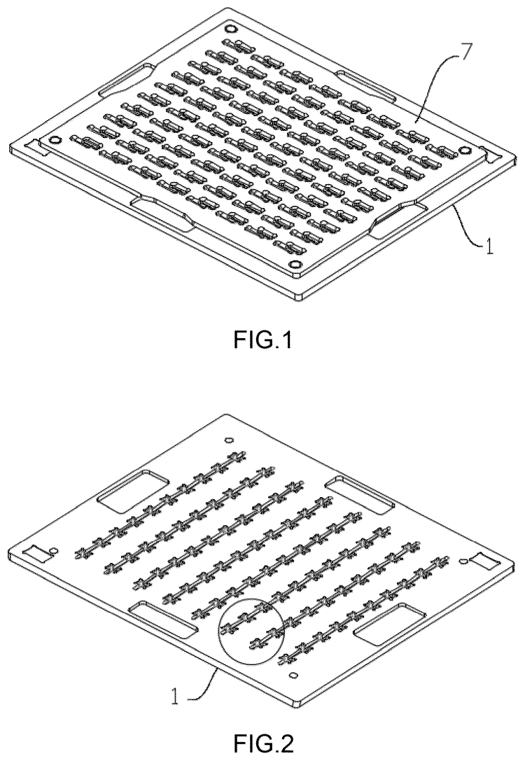

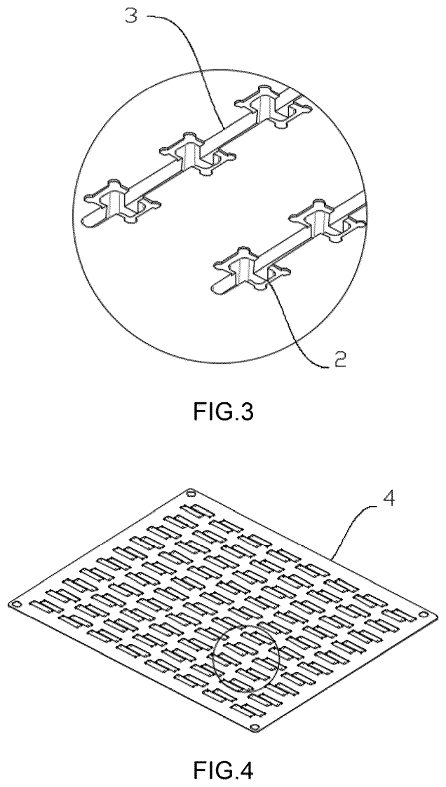

To solve the technical problems described in the Background, as illustrated in FIGS. 1-3, a chip mounting fixture is provided, including: a fixture body 1, where the fixture body 1 is provided with chip slots 2 that are uniformly distributed in an array and configured for accommodating chips, inwardly recessed wire slots 3 are formed at the chip slots 2, and the wire slots 3 extend to outer sides of the chip slots 2.

In this implementation, each of the chip slots 2 is recessed along an end face of the fixture body 1 to a certain depth, a depth of the recess depends on a thickness of the chip, and the chip slots 2 are arranged on the fixture body 1 in the form of an array. Further, rounded corners are designed at four corners of each of the chip slots 2 to avoid damage to four corners of a chip during processing. In order to facilitate extraction of the chip after processing, the wire slots 3 are designed at positions of the chip slots 2, the wire slot 3 is designed for each of the chip slots 3, and each of the wire slots 3 extends outside the corresponding chip slot 3 in a length direction. Alternatively, the wire slots 3 between the chip slots 2 in a same linear direction can be communicated with each other.

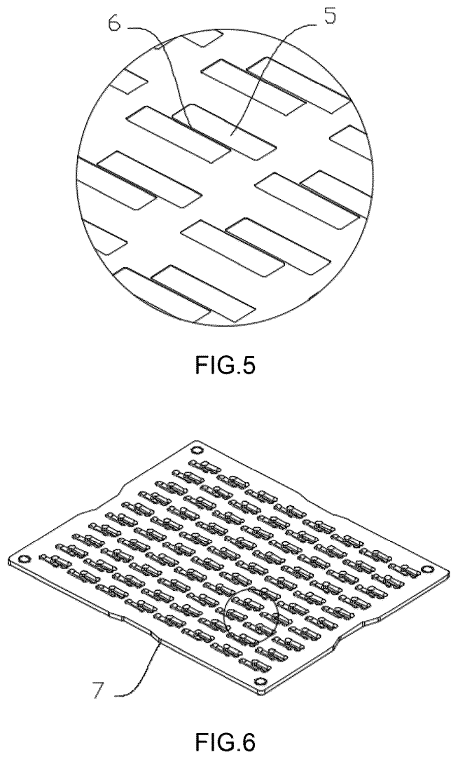

As illustrated in FIGS. 4-5, the chip mounting fixture includes a limiting plate 4, the limiting plate 4 is mounted on the fixture body 1, and the limiting plate 4 is provided with one or more solder paste slots 5 fitted with the chip slots 2. The limiting plate 4 is configured to apply solder paste on a specific position of the chip to form a solder paste band, and the limiting plate 4 is added to improve accuracy and quality of applying solder paste.

In the following embodiment, two solder paste slots 5 are arranged at a corresponding position of the chip slot 2, the two solder paste slots 5 are arranged adjacent to each other, and the two solder paste slots 5 are arranged in a staggered manner, that is, the two solder paste slots 5 are arranged to be one behind the other. There is a certain distance between the adjacent solder paste slots 5, and compression bands 6 are expressed on a surface of the limiting plate 4. During use, the compression band 6 spans over the chip slot 2, such that the chip on the chip slot 2 can be pressed and further fixed on the chip slot 2.

The limiting plate 4 is fixed to the fixture body 1 by means of magnetic attraction. A magnetic attraction structure can be designed on the limiting plate 4 and the fixture body 1, and the limiting plate 4 can be quickly mounted on the fixture body 1 by means of magnetic attraction, thereby improving work efficiency.

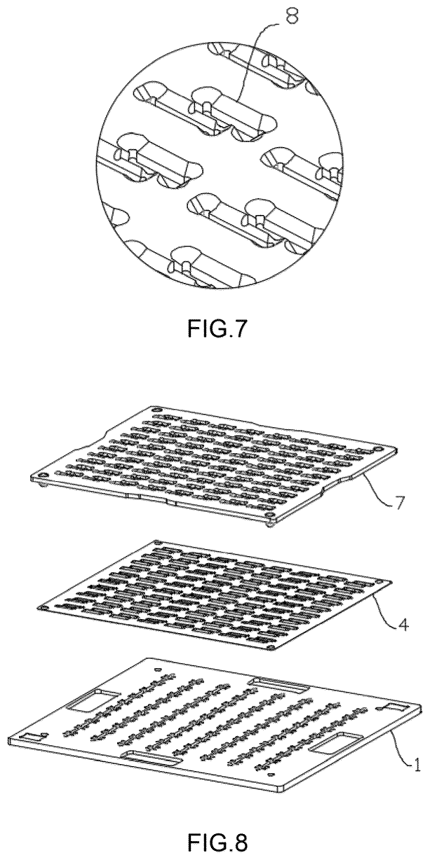

As illustrated in FIGS. 6-8, the chip mounting fixture includes a limiting fixture 7, and the limiting fixture 7 is provided with one or more pin slots 8 fitted with the chip slot 2 and configured for placing straight pins or square pins.

In implementation, the limiting fixture 7 is configured to limit the straight pins or the square pins, and the pin slot 8 has a through structure. In use, under the action of surface mount technology (SMT), the square pin or the straight pin is moved to the designated pin slot 8, and the square pin or the straight pin cooperates with the chip coated with solder paste below through the pin slot 8.

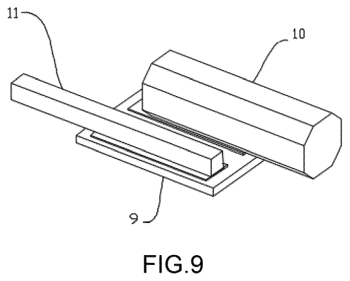

As illustrated in FIG. 9, the chip product is produced by using the above fixture.

An actual operation process of using the above chip mounting fixture is provided, and the chip mounting fixture includes the fixture body 1, the limiting plate 4 and the limiting fixture 7. Positioning holes are formed at the four corners of the fixture body 1, the limiting plate 4 and the limiting fixture 7, pin columns are arranged at four corners of the limiting fixture 7, corresponding pin column holes are formed at four corners of the limiting plate 4, positioning columns are arranged at four corners of the fixture body 1, and the pin columns of the limiting fixture 7 are matched and fixed with the positioning columns of the fixture body 1 through the pin column holes of the limiting plate 4. A magnetic component with magnetic properties is mounted on the fixture body 1, the limiting plate 4 can be matched with the fixture body 1 through magnetic attraction and fixation, and four recessed hand grooves are formed on the fixture body to facilitate movement thereof.

In use, the chip is placed in the chip slot 2 of the fixture body 1; the limiting plate 4 is mounted on the fixture body 1 by means of magnetic attraction, solder paste is coated onto a bonding pad surface of the chip through the solder paste slot 5 of the limiting plate 4 to form a solder paste band, and the compression band 6 formed between the solder paste slots 5 compresses the chip (two solder paste bands of the chip are needed, so two solder paste slots 5 are required); and the limiting fixture 7 is placed on the limiting plate 4, the SMT is used to place the straight pin/the square pin in the pin slot 8 and cooperate with the solder paste band for chip mounting, and the chip is extracted from the fixture after completing the above operation. An opening of the pin slot 8 is designed to have an involute slot structure, to facilitate mounting of the straight pin/the square pin.

Different from the traditional chip mounting process, the above operation process enables more accurate solder paste coating and chip mounting, and overall quality of the processed chip is improved.

The foregoing descriptions are not intended to limit the technical scope of the present disclosure. Therefore, any alteration, equivalent change and modification which are made to the above embodiments in accordance with the technical essence of the present disclosure all fall within the scope of protection of the technical solution of the present disclosure.

Type the free content description paragraph of the sequence listing here.

1. A chip mounting fixture, comprising: a fixture body, wherein the fixture body is provided with chip slots that are uniformly distributed in an array and configured for accommodating chips, inwardly recessed wire slots are formed at the chip slots, and the wire slots extend to outer sides of the chip slots;
further comprising a limiting plate, wherein the limiting plate is mounted on the fixture body. the limiting plate is provided with one or more solder paste slots fitted with the chip slots, two solder paste slots are arranged at a corresponding position of the chip slot, the two solder paste slots are arranged in a staggered manner, and a compression band that spans over the chip slot is formed by the two solder paste slots; and
further comprising a limiting fixture, wherein the limiting fixture is provided with one or more pin slots fitted with the chip slot and configured for placing straight pins or square pins.

2. The chip mounting fixture according to claim 1, wherein the wire slots between the chip slots in a same linear direction can be communicated with each other.

3. The chip mounting fixture according to claim 1, wherein the limiting plate is fixed to the fixture body by means of magnetic attraction.

4. A chip mounting process, comprising:
the chip is placed in the chip slot of the fixture body; the limiting plate is provided with a magnetic element, the limiting plate is mounted on the fixture body by means of magnetic attraction, solder paste is coated onto a bonding pad surface of the chip through the solder paste slot of the limiting plate to form a solder paste band, and the compression band formed between the solder paste slots compresses the chip; and the limiting fixture is placed on the limiting plate, the straight pin/the square pin is placed in the pin slot and attached to the solder paste band for chip mounting, and the chip is extracted from the fixture after completing the above operation.

5. The chip mounting process according to claim 4, wherein the straight pin/the square pin is attached to the solder paste band of the chip through surface mount technology (SMT).

6. The chip mounting process according to claim 4, wherein the straight pin/the square pin is placed in the pin slot and attached to the solder paste band for chip mounting, and an opening of the pin slot is designed to have an involute slot structure.

7. The chip mounting process according to claim 4, wherein pin columns are arranged at four corners of the limiting fixture, corresponding pin column holes are formed at four corners of the limiting plate, positioning columns are arranged at four corners of the fixture body, and the pin columns of the limiting fixture are matched and fixed with the positioning columns of the fixture body through the pin column holes of the limiting plate; and one or move recessed hand grooves are formed on the fixture body.

8. (canceled)

9. (canceled)

10. (canceled)
